(19) United States
(12) Patent Application Publication
(10) Pub. No.: US 2025/0329588 A1
(43) Pub. Date: Oct. 23, 2025

(54) TSV ELECTRICAL CONNECTION STRUCTURE HAVING HIGH ASPECT RATIO AND MANUFACTURING METHOD THEREFOR

(71) Applicant: WUHAN XINXIN SEMICONDUCTOR MANUFACTURING CO., LTD., Wuhan (CN)

(72) Inventors: Beibei SHENG, Wuhan (CN); Changbao ZHAO, Wuhan (CN); Xuepin TAN, Wuhan (CN); Daohong YANG, Wuhan (CN); Peng SUN, Wuhan (CN)

(21) Appl. No.: 18/881,515

(22) PCT Filed: Nov. 4, 2022
(86) PCT No.: PCT/CN2022/129779

§ 371 Date: Jan. 6, 2025

(30) Foreign Application Priority Data
Jul. 29, 2022 (CN) 202210907959.8

(51) Int. Cl. H01L 21/768; H01L 23/00; H01L 23/48

(52) U.S. Cl. CPC H01L 21/76898; H01L 23/481; H01L 24/05; H01L 2224/05025

(57) ABSTRACT

The present invention relates to a TSV electrical interconnect structure having a high aspect ratio and method of manufacturing it. In the method, a backside via and a backside contact pad connected to the backside via are formed on a backside of the semiconductor base. A front-side via connected to the backside via is then formed in the front side of the semiconductor base, obtaining a TSV which electrically connects the front side and backside of the semiconductor base that has a thickness greater than or equal to 150 μm. The TSV has an aspect ratio higher than 20, which can meet the requirements of package-level matching. The TSV electrical interconnect structure having a high aspect ratio can be connected to a package substrate or a PCB board through the backside contact pad. A rewiring layer on the front side of the semiconductor base is connected to the front-side via, and the TSV electrical interconnect structure having a high aspect ratio can provide an interconnection through the rewiring layer. Moreover, one or more other semiconductor bases may be stacked on the front side.

### TECHNICAL FIELD

The present invention relates to the field of semiconductor technology and, in particular, to a high aspect ratio through silicon via (TSV) based electrical interconnect structure and a method of manufacturing the structure.

### BACKGROUND

As systems on a chip (SOCs) are becoming larger and larger, three-dimensional (3D) integration technology is gaining increasing popularity because it provides effectively reduced horizontal footprints of micro-electromechanical systems (MEMS) on printed circuit boards (PCBs), shorter interconnection lengths and reduced signal delays. Therefore, this technology is advantageous in allowing systems to be compacter, have higher performance and consume less power.

Through silicon vias (TSVs) provide a solution for interconnecting stacked chips in 3D integration technology. TS Vs provide the advantages of, among others, small size, high density, high integration, small time delays. Using TSVs in a product can greatly reduce its volume and weight. At present, TSVs are used as mainstream interconnects for integration and miniaturization of radio frequency (RF) systems.

In some applications, it is desirable both to use a thick substrate and to electrically connect its front side to backside. For example, in some package modules including one or more semiconductor components, it is necessary to form high aspect ratio TSV electrical interconnect structures for package-level matching, as interposers, or for connecting a PCB.

However, due to relative low aspect ratios, conventional TSV processes only support small substrate thicknesses that cannot meet the requirements of package-level matching.

### SUMMARY

The present invention provides a method of manufacturing a TSV electrical interconnect structure having a high aspect ratio, which can electrically connect a front side of a thick semiconductor base to its backside, as desired by package-level matching. The invention also provides such an electrical interconnect structure.

In one aspect, the present invention provides a method of manufacturing a TSV electrical interconnect structure having a high aspect ratio, including:
providing a semiconductor base having a front side and a backside opposing the front side;
bonding the semiconductor base to a first carrier so that the backside of the semiconductor base remains exposed, and then thinning the semiconductor base to a preset thickness greater than or equal to 150 μm;
forming a backside via in the semiconductor base, which extends from the backside of the semiconductor base into the semiconductor base;
forming a backside contact pad on the backside of the semiconductor base, which is connected to the backside via;
bonding the semiconductor base to a second carrier and removing the first carrier, exposing the front side of the semiconductor base;
forming a front-side via in the semiconductor base, which extends from the front side of the semiconductor base into the semiconductor base and is electrically connected to the backside via so that the two constitute a TSV having an aspect ratio higher than 20; and
forming a rewiring layer on the front side of the semiconductor base, which is connected to the front-side via, and then removing the second carrier.

Optionally, the preset thickness may be less than or equal to 300 μm.

Optionally, a diameter of the front-side via may be smaller than a diameter of the backside via that it is electrically connected to.

Optionally, the diameter of the backside via may be not smaller than 7 μm, and the diameter of the front-side via may be not greater than 6 μm.

Optionally, the step of forming the backside via may include:
forming a backside hole in the backside of the semiconductor base;
forming a first insulating layer on an inner surface of the backside hole; and
filling a conductive material in the backside hole, thereby forming the backside via.

Optionally, the step of forming the backside contact pad may include:
forming a second insulating layer on the backside via;
forming an opening in the second insulating layer, which exposes the backside via; and
filling a conductive material in the opening, thereby forming the backside contact pad.

Optionally, the method may further include, before the semiconductor base is bonded to the second carrier,
forming a third insulating layer on the backside of the semiconductor base, which covers the second insulating layer and the backside contact pad.

Optionally, the step of forming the front-side via may include:
forming a front-side hole in the front side of the semiconductor base, which extends through a partial thickness of the semiconductor base and exposes the backside via, wherein the conductive material in the backside via serves as an etch stop layer during the formation of the front-side hole;
forming a fourth insulating layer on a side surface of the front-side hole; and
filling a conductive material in the front-side hole, thereby forming the front-side via.

Optionally, the semiconductor base may be bonded to the first and second carriers by fusion bonding, or by adhesive bonding.

In another aspect, the present invention provides a TSV electrical interconnect structure having a high aspect ratio, including:
a semiconductor base having a front side and a backside opposing the front side and having a thickness greater than or equal to 150 μm;
a TSV formed in the semiconductor base, the TSV including a backside via and a front-side via, which are electrically connected to each other, the backside via extending from the backside of the semiconductor base into the semiconductor base, the front-side via extending from the front side of the semiconductor base into the semiconductor base, the TSV having an aspect ratio higher than 20;
a backside contact pad, which is located on the backside of the semiconductor base and connected to the backside via; and
a rewiring layer, which is located on the front side of the semiconductor base and connected to the front-side via.

In the method of the present invention, the semiconductor base is thinned to a thickness greater than or equal to 150 μm and then backed with the first carrier, followed by the formation of the backside via at the backside of the semiconductor base and the backside contact pad connected to the backside via. After that, the semiconductor base is backed with the second carrier, and the front-side via is formed at the front side of the semiconductor base. The front-side and backside vias are connected to each other and make up the TSV having an aspect ratio higher than 20. In this way, the front side and backside of the semiconductor base that has a thickness greater than or equal to 150 μm are electrically connected, as desired for package-level matching.

Since one or more electronic components are usually formed at the front side of the semiconductor base, according to the present invention, the backside via is formed at the backside first. As the backside via does not occupy any area of the device region, it is allowed to be wide and deep. The front-side via is then formed so as to be narrow and shallow to reduce its influence on the area of the device region. Additionally, during the formation of the front-side hole for the front-side via, the conductive material in the backside via can serve as an etch stop layer, avoiding over-etching of the semiconductor base around the backside via, which may adversely affect the reliability of the resulting TSV electrical interconnect structure having a high aspect ratio.

In the TSV electrical interconnect structure having a high aspect ratio of the present invention, the thickness of the semiconductor base is greater than or equal to 150 μm, and the TSV formed in the semiconductor base includes the backside via and the front-side via that are electrically connected to each other. The aspect ratio of the TSV is higher than 20 and can meet the requirements of package-level matching. The backside contact pad on the backside of the semiconductor base is connected to the backside via, and the TSV electrical interconnect structure having a high aspect ratio can be connected to a package substrate or a PCB board through the backside contact pad. The rewiring layer on the front side of the semiconductor base is connected to the front-side via, and the TSV electrical interconnect structure having a high aspect ratio can provide an interconnection through the rewiring layer. Further, one or more other semiconductor bases may be stacked on the front side.

### BRIEF DESCRIPTION OF THE DRAWINGS

FIG. 1 is a flowchart of a method of manufacturing a TSV electrical interconnect structure having a high aspect ratio according to an embodiment of the present invention.

FIGS. 2 to 9 are schematic cross-sectional views of structures resulting from steps in a method of manufacturing a TSV electrical interconnect structure having a high aspect ratio according to an embodiment of the present invention.

### LIST OF REFERENCE NUMERALS

100 semiconductor base; 100a front side; 100b backside; 200 first carrier; 101 front-side dielectric layer; 102 first insulating layer; 110 backside via; 103 second insulating layer; 120 backside contact pad; 104 third insulating layer; 300 second carrier; 105 fourth insulating layer; 106 fifth insulating layer; 106a silicon oxide layer; 106b silicon nitride layer; 141 rewiring via; 140 rewiring layer; 107 sixth insulating layer.

### DETAILED DESCRIPTION

TSV electrical interconnect structure having a high aspect ratio and methods of manufacturing such an electrical interconnect structure according to the present invention will be described in greater detail below with reference to the accompanying drawings, which illustrate specific embodiments thereof. From the following description, advantages and features of the present invention will be more apparent. It is to be noted that the terms “first”, “second” and the like may be used herein to distinguish between similar elements without necessarily implying any particular ordinal or chronological sequence. It will be understood that the terms so used are interchangeable, whenever appropriate. Likewise, if a method is described herein as including a series of steps, the order of these steps as presented herein is not necessarily the only order in which they can be performed, and certain ones of the stated steps may be possibly omitted and/or certain other steps not described herein may be possibly added to the method.

Note that the figures are provided in a very simplified form not necessarily drawn to exact scale for the only purpose of helping explain the disclosed embodiments in a more convenient and clearer way. It will be understood that, as used herein, spatially relative terms are intended to encompass different orientations of the device in use or operation in addition to the orientation depicted in the figures. For example, if the device in the figures is inverted or otherwise oriented (e.g., rotated), the exemplary term “over” can encompass an orientation of “under” and other orientations. Throughout the drawings, if any component is identical to a labeled one, although such components may be easily identifiable in all the figures, in order for a more clear description of labels to be obtained, not all identical components are labeled and described in the following description and accompanying drawings.

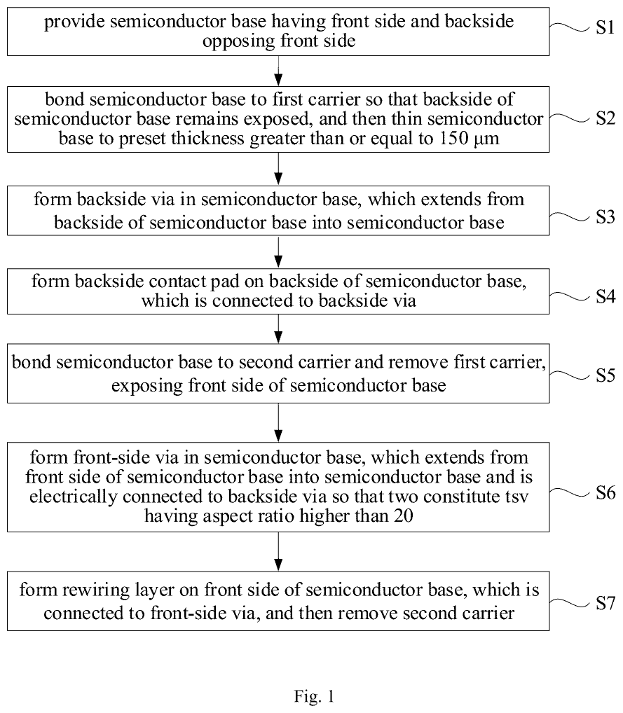

Referring to FIG. 1, a method of manufacturing a TSV electrical interconnect structure having a high aspect ratio according to an embodiment of the present invention includes the steps of:
S1) providing a semiconductor base, the semiconductor base has a front side and a backside opposing the front side;
S2) bonding the semiconductor base to a first carrier so that the backside of the semiconductor base remains exposed, and then thinning the semiconductor base to a preset thickness, the preset thickness is greater than or equal to 150 μm;
S3) forming a backside via in the semiconductor base, which extends from the backside of the semiconductor base into the semiconductor base;
S4) forming a backside contact pad on the backside of the semiconductor base, which is connected to the backside via;
S5) bonding the semiconductor base to a second carrier and removing the first carrier, thus exposing the front side of the semiconductor base;
S6) forming a front-side via in the semiconductor base, which extends from the front side of the semiconductor base into the semiconductor base and is electrically connected to the backside via so that the two constitute a TSV having an aspect ratio higher than 20; and
S7) forming a rewiring layer on the front side of the semiconductor base, which is connected to the front-side via, and then removing the second carrier.

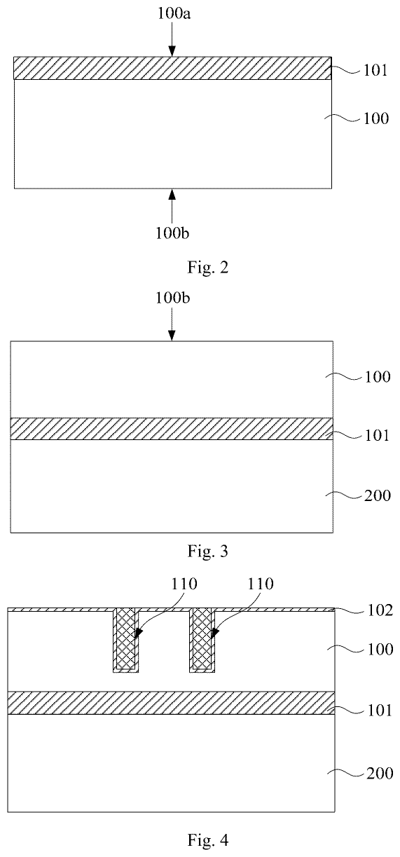

The method of manufacturing a TSV electrical interconnect structure having a high aspect ratio is further described below with reference to FIGS. 2 to 9.

FIG. 2 is a schematic cross-sectional view of a semiconductor base provided in the method of manufacturing a TSV electrical interconnect structure having a high aspect ratio according to an embodiment of the present invention. As shown in FIG. 2, in step S1, a semiconductor base 100 is provided, the semiconductor base 100 has a front side 100a and a backside 100b opposing the front side 100a.

The semiconductor base 100 may include a semiconductor substrate, which is, for example, a silicon substrate, a germanium (Ge) base, a silicon germanium (SiGe) substrate, a silicon-on-insulator (SOI) substrate, a germanium-on-insulator (GOI) substrate or the like. The semiconductor base 100 may have been processed by a series of semiconductor processes, the semiconductor base 100 may include one or more electronic components formed in the semiconductor substrate and a front-side dielectric layer 101 covering the electronic components. The electronic components are formed at the front side 100a of the semiconductor base 100, and the backside 100b of the semiconductor base 100 opposes the front side 100a. The electronic components may include at least one of a MOS device, a sensor device, a memory device and a passive device. The semiconductor base 100 may have a thickness greater than 300 μm, or even greater than 600 μm.

FIG. 3 is a schematic cross-sectional view of a structure resulting from bonding the semiconductor base to a first carrier in the method of manufacturing a TSV electrical interconnect structure having a high aspect ratio according to an embodiment of the present invention. Referring to FIG. 3, in step S2, the semiconductor base 100 is bonded to a first carrier 200 so that the backside 100b of the semiconductor base 100 remains exposed, and the semiconductor base 100 is thinned to a preset thickness, the preset thickness is greater than or equal to 150 μm.

The first carrier 200 can serve to carry the semiconductor base 100 when semiconductor processes are performed on the backside 100b thereof. The first carrier 200 may be a silicon wafer or any other type of backing. The semiconductor base 100 may be bonded to the first carrier 200 by adhesive or fusion bonding. The backside of the thinned semiconductor base 100 is also denoted as 100b, in order to show the association.

The semiconductor base 100 may be thinned from the backside by etching, polishing, or both, or one or more other known processes. According to embodiments of the present invention, the thickness of the thinned semiconductor base 100 is controlled to be greater than or equal to 150 μm, in order to allow the subsequent formation of the TSV electrical interconnect structure having a high aspect ratio, which can meet the thickness requirements of some packaging applications. Optionally, the thinned semiconductor base 100 may have a thickness less than or equal to 300 μm.

FIG. 4 is a schematic cross-sectional view of a structure resulting from forming a backside via in the method of manufacturing a TSV electrical interconnect structure having a high aspect ratio according to an embodiment of the present invention. As shown in FIG. 4, in step S3, a backside via 110 is formed at the backside 100b of the semiconductor base 100, the backside via 110 extends from the backside 100b of the semiconductor base 100 into the semiconductor base.

In particular, step S3 may include the following sub-steps.

At first, photolithography and etching processes may be carried out. For example, photoresist may be coated on the backside 100b of the semiconductor base 100 and then exposed and developed, exposing the region to be etched. An anisotropic etching process may be performed on the semiconductor base 100 to form a backside hole, the bottom of which is situated within the semiconductor base 100.

Subsequently, a first insulating layer 102 may be formed with covering the backside 100b of the semiconductor base 100 and lining the backside hole, the first insulating layer 102 is able to insulate the semiconductor base 100 from the conductive material to be subsequently filled in the backside hole. The first insulating layer 102 may include at least one of silicon oxide, silicon nitride and silicon oxynitride. In this embodiment, it is silicon oxide (linear oxide), for example.

After that, an electroplating process may be carried out to deposit a conductive material in the backside hole and on a top surface of the first insulating layer 102. For example, a seed layer (e.g., a Ti/Cu layer) may be first formed, which lines the backside hole and covers the top surface of the first insulating layer 102, and the resulting electrical interconnect structure may be immersed in an electroplating solution. Deposition of the conductive material in the backside hole and on the top surface of the first insulating layer may be then initiated under given conditions. The conductive material may be copper, for example, which may fill up the backside hole at the end of the electroplating process.

Afterwards, a planarization process (e.g., chemical mechanical polishing (CMP)) may be carried out to flatten the conductive material. As a result of this planarization process, the conductive material above the top surface of the first insulating layer 102 may be removed, with the conductive material retained in the backside hole forming the backside via 110. If required, one or more such backside vias 110 may be formed at the backside 100b of the semiconductor base 100.

Since there is no electronic component at the backside 100b of the semiconductor base 100, in this embodiment, the backside via 110 is allowed to reach a great depth while ensuring desirable filling of the electroplating process. In this way, the subsequently-formed front-side via is allowed to be relatively narrow and shallow and therefore less affect the area of the front-side device region. For example, the backside hole may have an aspect ratio of about 10-15. The backside via 110 may have a diameter, for example, not less than 7 μm, such as 9 μm, and a depth, for example, of about 100 μm. In addition, considering the limitations on the overall size of the structure, the diameter of the backside via 110 may lie in the range of 7-20 μm. The backside via 110 may show little variation in diameter across its depth. Here, the diameter of the backside via 110 may be measured at different depths thereof.

FIG. 5 is a schematic cross-sectional view of a structure resulting from forming a backside contact pad in the method of manufacturing a TSV electrical interconnect structure having a high aspect ratio according to an embodiment of the present invention. As shown in FIG. 5, in step S4, a backside contact pad 120 is formed on the backside 100b of the semiconductor base 100, the backside contact pad 120 is connected to the backside via 110 as described above. The backside contact pad 120 may be used to connect the structure being fabricated to a package substrate, or to a PCB board.

In particular, step S4 may include the following sub-steps.

First of all, a second insulating layer 103 may be formed on the backside via 110. The second insulating layer 103 may include, for example, at least one of silicon oxide, silicon nitride and silicon oxynitride. In this embodiment, it is silicon oxide, for example.

Next, photolithography and etching processes may be carried out to form an opening in the second insulating layer 103, which exposes the backside via 110.

Subsequently, an electroplating process is performed to deposit a conductive material on a top surface of the second insulating layer 103 in the opening. The conductive material may be copper, for example.

Afterwards, a planarization process (e.g., CMP) may be carried out to flatten the conductive material. As a result of this planarization process, the conductive material deposited above the top surface of the second insulating layer 103 may be removed, with the conductive material retained in the opening forming the backside contact pad 120, the backside contact pad 120 is connected to the backside via 110.

In practical applications, any desired number of (e.g., one or more) backside contact pads 120 may be formed, and each backside contact pad 120 may be connected to any desired number of (e.g., one or more) backside vias 110. Referring to FIG. 5, for example, during the formation of the backside contact pad 120, the opening formed in the second insulating layer 103 may expose adjacent two backside vias 110. In this way, during the formation of the backside contact pad 120 via depositing the conductive material in the opening, the backside contact pad 120 contacts both the backside vias 110. This can result in resistance reductions.

Referring to FIG. 5, after the backside contact pad 120 is formed and before step S5 is performed, a third insulating layer 104 may be formed on the backside 100b of the semiconductor base 100, the third insulating layer 104 covers the second insulating layer 103 and the backside contact pad 120. The third insulating layer 104 can provide protection to the backside contact pad 120, for example, during the subsequent bonding and removal of the second carrier. The third insulating layer 104 may include, for example, at least one of silicon oxide, silicon nitride and silicon oxynitride. In this embodiment, it is silicon oxide, for example.

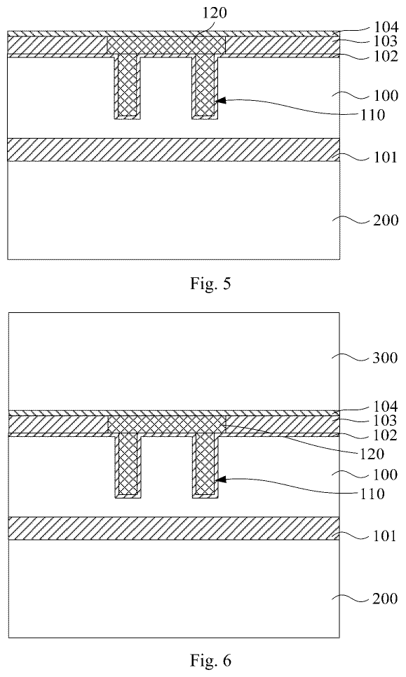

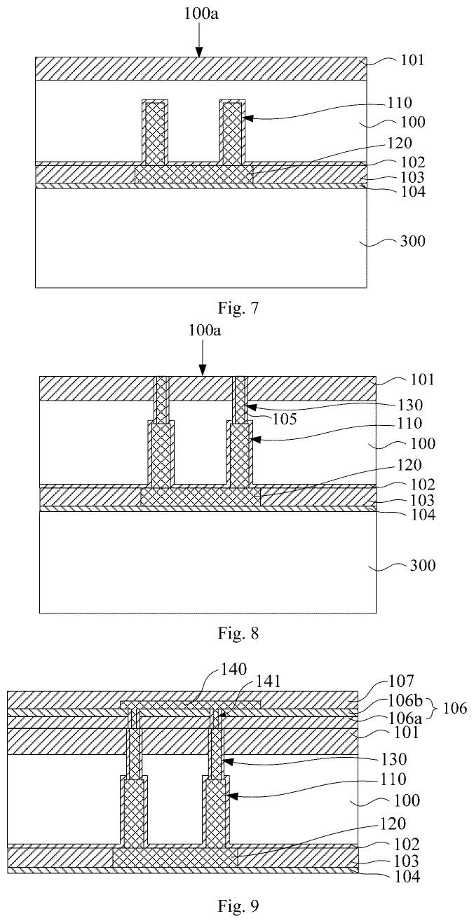

FIG. 6 is a schematic cross-sectional view of a structure resulting from bonding a second carrier in the method of manufacturing a TSV electrical interconnect structure having a high aspect ratio according to an embodiment of the present invention. FIG. 7 is a schematic cross-sectional view of a structure resulting from removing the first carrier in the method of manufacturing a TSV electrical interconnect structure having a high aspect ratio according to an embodiment of the present invention. As shown in FIGS. 6 and 7, in step S5, the semiconductor base 100 is bonded to a second carrier 300, and first carrier 200 is removed, exposing the front side 100a of the semiconductor base 100.

The second carrier 300 may be a silicon wafer or any other type of backing. The semiconductor base 100 may be bonded to the second carrier 300 by adhesive or fusion bonding. The removal of the first carrier 200 may be accomplished by, for example, heating or cutting.

FIG. 8 is a schematic cross-sectional view of a structure resulting from forming a front-side via in the method of manufacturing a TSV electrical interconnect structure having a high aspect ratio according to an embodiment of the present invention. As shown in FIG. 8, in step S6, a front-side via 130 is formed in the semiconductor base 100, the front-side via 130 extends from the front side 100a of the semiconductor base 100 into the semiconductor base 100 and is electrically connected to the backside via 110.

In particular, step S6 may include the following sub-steps.

At first, photolithography and etching processes may be carried out. For example, photoresist may be coated on a top surface of the front-side dielectric layer 101, and then exposed and developed, exposing the region to be etched. An anisotropic etching process may be performed on the front-side dielectric layer 101 and the semiconductor base 100 to form a front-side hole. Any desired number of front-side holes may be formed. For example, one or more front-side holes may be formed. The front-side hole extends through the front-side dielectric layer 101 and partial thickness of the semiconductor base 100, exposing the backside via 110 on the front side 100a.

After that, a fourth insulating layer 105 may be formed on a side surface of the front-side hole. For example, the fourth insulating layer 105 may be a silicon oxide formed on the side surface of the front-side hole by dry or wet oxidation. The fourth insulating layer 105 can insulate the semiconductor base 100 from the conductive material to be subsequently filled in the front-side hole.

Subsequently, an electroplating process may be carried out to deposit a conductive material (e.g., Cu) in the front-side hole and on the front-side dielectric layer 101. At the end of the electroplating process, the conductive material may fill up the front-side hole.

Afterwards, a planarization process (e.g., CMP) may be carried out to flatten the conductive material. As a result of this planarization process, the conductive material above the front-side dielectric layer 101 may be removed, with the conductive material retained in the front-side hole forming the front-side via 130.

The front-side hole may be located in correspondence with the backside via 110, for example, in coaxiality with the backside hole of the backside via 110. Moreover, the front-side hole is preferred to have a diameter smaller than the diameter of the backside hole. This can not only reduce the influence on the front-side device region, but can also avoid over-etching of the semiconductor base around the backside via 110, which may otherwise occur if the front-side hole is somewhat offset from the backside via 110 and affect the reliability of the resulting electrical interconnect structure. For example, the diameter of the front-side via 130 may be at least 1-2 μm less than that of the backside via 110. The diameter of the front-side via 130 may lie in the range of 3-18 μm. Further, the diameter of the front-side via 130 may be, for example, not greater than 6 μm.

In this embodiment, the front-side hole is etched in the semiconductor base 100 so that the conductive material in the backside via 110 is exposed at the bottom of the front-side hole. In this way, the front-side via 130 is electrically connected to the backside via 110, and the two constitute a TSV that connects the front side of the semiconductor base 100 to its backside. Additionally, the conductive material in the backside via 110 may serve as an etch stop layer to avoid the semiconductor base 100 around the backside via 110 from being over-etched, ensuring good reliability of the resulting electrical interconnect structure.

Using the method discussed above, one or more such TSVs may be formed in the semiconductor base, each including a front-side via 130 and a backside via 110, which are electrically connected to each other. The aspect ratio of the TSV is defined as a ratio of the thickness of the semiconductor base 100 to the diameter of the front-side via 130, or the diameter of the backside via 110, whichever is smaller. For example, in this embodiment, the thickness of the semiconductor base 100 may be 150 μm, the diameter of the front-side via 130 may be 5 μm, and the diameter of the backside via 110 may be 9 μm. Therefore, the aspect ratio of the TSV is 30 (150 divided by 5).

FIG. 9 is a schematic cross-sectional view of a structure resulting from forming a rewiring via and a rewiring layer in the method of manufacturing a TSV electrical interconnect structure having a high aspect ratio according to an embodiment of the present invention. As shown in FIG. 9, in step S7, a rewiring layer 140 is formed on the front side 100a of the semiconductor base 100, the rewiring layer 140 is connected to the front-side via 130, and the second carrier 300 is then removed.

In particular, step S7 may include the following sub-steps.

First of all, as shown in FIG. 9, a fifth insulating layer 106 may be formed on the front-side dielectric layer 101, the fifth insulating layer 106 may include, for example, at least one of silicon oxide, silicon nitride and silicon oxynitride. In this embodiment, it may include, for example, a silicon oxide layer 106a and a silicon nitride layer 106b, which are stacked one above the other.

Next, photolithography and etching processes may be carried out to form a through hole, which extends through both the silicon nitride layer 106b and the silicon oxide layer 106a and exposes the front-side via 130. A bond layer (e.g., a Ti/TiN layer) may be then formed on a side surface of the through hole.

Subsequently, a metal material (e.g., aluminum, or an aluminum-copper alloy) may be deposited in the through hole and on the fifth insulating layer 106. The metal material that fills the through hole serves as the rewiring via 141, the rewiring via 141 is connected to the front-side via 130. The rewiring via 141 may have a diameter, which is, for example, smaller than that of the front-side via 130.

Afterwards, the metal material on the fifth insulating layer 106 may be patterned into the rewiring layer 140, the rewiring layer 140 is connected to the front-side via 130 via the rewiring via 141.

Further, in order to provide protection to the rewiring layer 140 during the removal of the second carrier 300 and facilitate the performance of subsequent 3D integration processes on the front side 100a, a sixth insulating layer 107 may be formed on the rewiring layer 140. The sixth insulating layer 107 may be, for example, silicon oxide and may cover the rewiring layer 140 and the fifth insulating layer 106. Referring to FIG. 9, the second carrier 300 may be removed, after the sixth insulating layer 107 is formed.

After the above steps are completed, the TSV electrical interconnect structure having a high aspect ratio is formed in the semiconductor base 100, which connects the front side 100a of the semiconductor base 100 to the backside 100b thereof. The high aspect ratio TSV includes the backside via 110 and the front-side via 130 that are electrically connected to each other. A total depth of the high aspect ratio TSV is approximately equal to the thickness of the semiconductor base 100, and may be greater than or equal to 150 μm. Its aspect ratio may be higher than 20, which can meet the requirements of package-level matching. The TSV electrical interconnect structure having a high aspect ratio further includes the rewiring layer 140 on the front side 100a and the backside contact pad on the backside 100b. This TSV electrical interconnect structure having a high aspect ratio can be used as an interposer for establishing a desired connection. It can also be used in a 3D integration process for manufacturing a 3D integrated module, which contains multiple stacked layers and has a high functional density, in which one or more other semiconductor bases may be stacked on the rewiring layer 140.

Embodiments of the present invention also provide a TSV electrical interconnect structure having a high aspect ratio obtainable according to the method discussed above. Referring to FIGS. 2 to 9, the TSV electrical interconnect structure having a high aspect ratio includes:
a semiconductor base 100, the semiconductor base 100 has a front side 100a and a backside 100b opposing the front side 100a, the semiconductor base 100 has a thickness greater than or equal to 150 μm;
a TSV formed in the semiconductor base 100, the TSV includes a backside via 110 and a front-side via 130, which are electrically connected to each other, the backside via 110 extends from the backside 100b of the semiconductor base 100 into the semiconductor base 100, the front-side via 130 extends from the front side 100a of the semiconductor base 100 into the semiconductor base 100, the TSV has an aspect ratio higher than 20;
a backside contact pad 120 located on the backside 100b of the semiconductor base 100, the backside contact pad 120 is connected to the backside via 110; and
a rewiring layer 140 located on the front side 100a of the semiconductor base 100, the rewiring layer 140 is connected to front-side via 130.

In some embodiments, in order to avoid the area of a device region from being affected and to allow the electrical interconnect structure to have improved reliability, the front-side via 130 has a diameter smaller than a diameter of the backside via 110 that it is electrically connected to. For example, the diameter of the backside via 110 may be not smaller than 7 μm, and the diameter of the front-side via 130 may be not greater than 6 μm.

In the TSV electrical interconnect structure having a high aspect ratio of the present invention, the thickness of the semiconductor base 100 is not smaller than 150 μm, and the TSV formed in the semiconductor base 100 includes the backside via 110 and the front-side via 130 that are electrically connected to each other. The aspect ratio of the TSV is higher than 20 and can meet the requirements of package-level matching, while not affecting the area of the device region and enabling the electrical interconnect structure to have increased reliability. The backside contact pad 120 located on the backside 100b of the semiconductor base 100 may be connected to at least one backside via 110, and the electrical interconnect structure may be connected to a package substrate or a PCB board by the backside contact pad 120. The rewiring layer 140 located on the front side 100a of the semiconductor base 100 can be connected to the front-side via 130 through the rewiring via 141, and the electrical interconnect structure can provide an interconnection through the rewiring layer 140. Further, one or more other semiconductor bases may be stacked on the front side 100a.

It is to be noted that the embodiments disclosed herein are described in a progressive manner, with the description of each embodiment focusing on its differences from others. Cross-reference can be made between the embodiments for their common or similar features.

While the invention has been described above with reference to several preferred embodiments, it is not intended to be limited to these embodiments in any way. In light of the teachings hereinabove, any person of skill in the art may make various possible variations and changes to the disclosed embodiments without departing from the scope of the invention. Accordingly, any and all such simple variations, equivalent alternatives and modifications made to the foregoing embodiments without departing from the scope of the invention are intended to fall within the scope thereof.

1. A method of manufacturing a through silicon via (TSV) electrical interconnect structure with a high aspect ratio, comprising:
providing a semiconductor base having a front side and a backside opposing the front side;
bonding the semiconductor base to a first carrier with the backside of the semiconductor base being exposed, and then thinning the semiconductor base to a preset thickness, the preset thickness being greater than or equal to 150 μm;
forming a backside via in the semiconductor base, which extends from the backside of the semiconductor base into the semiconductor base;
bonding the semiconductor base to a second carrier and removing the first carrier, exposing the front side of the semiconductor base; and
forming a front-side via in the semiconductor base, which extends from the front side of the semiconductor base into the semiconductor base and is electrically connected to the backside via, thereby forming a TSV having an aspect ratio higher than 20.

2. The method of claim 1, wherein the preset thickness is less than or equal to 300 μm.

3. The method of claim 1, wherein a diameter of the front-side via is smaller than a diameter of the backside via that the front-side via is electrically connected to.

4. The method of claim 3, wherein the diameter of the backside via is not smaller than 7 μm and the diameter of the front-side via is not greater than 6 μm.

5. The method of claim 1, wherein the step of forming the backside via comprises:
forming a backside hole in the backside of the semiconductor base;
forming a first insulating layer on an inner surface of the backside hole; and
filling a conductive material in the backside hole, thereby forming the backside via.

6. The method of claim 11, wherein the step of forming the backside contact pad comprises:
forming a second insulating layer on the backside via;
forming an opening in the second insulating layer, which exposes the backside via; and
filling a conductive material in the opening, thereby forming the backside contact pad.

7. The method of claim 6, further comprising, before the semiconductor base is bonded to the second carrier, forming a third insulating layer on the backside of the semiconductor base, which covers the second insulating layer and the backside contact pad.

8. The method of claim 1, wherein the step of forming the front-side via comprises:
forming a front-side hole in the front side of the semiconductor base, which extends through a partial thickness of the semiconductor base and exposes the backside via, wherein the conductive material in the backside via serves as an etch stop layer during the formation of the front-side hole;
forming a fourth insulating layer on a side surface of the front-side hole; and
filling a conductive material in the front-side hole, thereby forming the front-side via.

9. The method of claim 1, wherein the semiconductor base is bonded to the first carrier and the second carrier by fusion bonding, or by adhesive bonding.

10. A through silicon via (TSV) electrical interconnect structure with a high aspect ratio, comprising:
a semiconductor base having a front side and a backside opposing the front side, the semiconductor base having a thickness greater than or equal to 150 μm; and
a TSV formed in the semiconductor base, the TSV comprising a backside via and a front-side via, which are electrically connected to each other, the backside via extending from the backside of the semiconductor base into the semiconductor base, the front-side via extending from the front side of the semiconductor base into the semiconductor base, the TSV having an aspect ratio higher than 20.

11. The method of claim 1, further comprising forming a backside contact pad on the backside of the semiconductor base, which is connected to the backside via.

12. The method of claim 11, wherein at least two TSVs are formed in the semiconductor base, two adjacent TSVs are connected to a single backside contact pad on the backside of the semiconductor base and are interconnected on the front side of the semiconductor base through a rewiring layer.

13. The method of claim 1, wherein the aspect ratio of the TSV is 30.

14. The method of claim 1, further comprising forming a rewiring layer on the front side of the semiconductor base, which is connected to the front-side via, and then removing the second carrier.

15. The method of claim 14, further comprising:
forming a front-side dielectric layer on the front side of the semiconductor base;
forming a fifth insulating layer on the front-side dielectric layer; and
forming a sixth insulating layer covering the rewiring layer and the fifth insulating layer.

16. The TSV electrical interconnect structure of claim 10, further comprising a backside contact pad, which is located on the backside of the semiconductor base and connected to the backside via.

17. The TSV electrical interconnect structure of claim 16, wherein at least two TSVs are formed in the semiconductor base, two adjacent TSVs are connected to a single backside contact pad on the backside of the semiconductor base and are interconnected on the front side of the semiconductor base through a rewiring layer.

18. The TSV electrical interconnect structure of claim 10, wherein the aspect ratio of the TSV is 30.

19. The TSV electrical interconnect structure of claim 10, further comprising a rewiring layer, which is located on the front side of the semiconductor base and connected to the front-side via.

20. The TSV electrical interconnect structure of claim 19, further comprising:
a front-side dielectric layer formed on the front side of the semiconductor base;
a fifth insulating layer formed on the front-side dielectric layer; and
a sixth insulating layer covering the rewiring layer and the fifth insulating layer.
